(19) United States
(12) Patent Application Publication
(10) Pub. No.: US 2008/0149926 A1
(43) Pub. Date: Jun. 26, 2008

(54) SEMICONDUCTOR DEVICE HAVING TEST PATTERN FOR MEASURING EPITAXIAL PATTERN SHIFT AND METHOD FOR FABRICATING THE SAME

(76) Inventor: Chang Eun LEE, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/961,790

(22) Filed: Dec. 20, 2007

(30) Foreign Application Priority Data
Dec. 21, 2006 (KR) 10-2006-0131890

(51) Int. Cl. H01L 23/58; H01L 21/66

(52) U.S. Cl. 257/48; 438/18; 257/E23.002; 257/E21.531

(57) ABSTRACT

A semiconductor device having a test pattern for measuring epitaxial pattern shift is provided. The test pattern includes a semiconductor substrate having a first pattern formed therein; a first impurity region formed in the semiconductor substrate; an epitaxial layer formed on the semiconductor substrate, the epitaxial layer having a second pattern formed therein, wherein the second pattern corresponds to the first pattern; and a second impurity region formed in the epitaxial layer, the second impurity region in electrical contact with the first impurity region.

The present application claims the benefit of priority under 35 U.S.C. 119 to Korean Patent Application No. 10-2006-0131890, filed on Dec. 21, 2006, the entire contents of which are incorporated herewith by reference.

### BACKGROUND

The present invention relates to a semiconductor device having a test pattern for measuring epitaxial pattern shift, and a method for fabricating the same.

Silicon epitaxial deposition has been used in the manufacture of various semiconductor devices. However, after growing an epitaxial layer on a semiconductor substrate, conventional processes have addressed problems, such as wafer pattern alignment, and upper and lower mask overlay performance. Moreover, not only does epitaxial deposition have associated processing problems, but important parameters of the silicon epitaxial deposition, such as epitaxial thickness uniformity and epitaxial shift-induced distortion, need to be controlled. For example, lateral displacement, also known as epitaxial shift or pattern shift, may have important influences on a position having relative characteristics. Properties of the deposited epitaxial layer may vary according to various process variables, such as directivity of the semiconductor substrate, characteristics of a furnace for growing the epitaxial layer, process conditions, and the like.

FIGS. 1 to 3 are sectional views showing possible phenomena between a substrate 10 and an epitaxial layer 11 grown on substrate 10. As shown in FIG. 1, a pattern, denoted by points “a” and “b,” is shifted in a lateral direction away from the pattern formed on substrate 10, denoted by points “c” and “d,” as a result of the process for growing epitaxial layer 11. As shown in FIG. 2, a pattern is distorted such that a distance between points “a” and “b” of the pattern formed as epitaxial layer 11 is less than the distance between points “c” and “d” of the pattern formed on substrate 10, denoting a smaller pattern, as a result of the process for growing epitaxial layer 11. As shown in FIG. 3, the pattern is washed out, and not formed in epitaxial layer 11 as a result of the process for growing epitaxial layer 11. Phenomena described above are not easily measured by physical methods, because the boundary between substrate 10 and epitaxial layer 11 is often not clear.

### SUMMARY

Embodiments consistent with the present invention provide a semiconductor device having a test pattern for measuring pattern shifts, and a method for fabricating the semiconductor device.

In one embodiment consistent with the present invention, there is provided a semiconductor device having a test pattern for measuring epitaxial pattern shifts, the test pattern comprising: a semiconductor substrate having a first pattern formed therein; a first impurity region formed in the semiconductor substrate; an epitaxial layer formed on the semiconductor substrate, the epitaxial layer having a second pattern formed therein, wherein the second pattern corresponds to the first pattern; and a second impurity region formed in the epitaxial layer, the second impurity region in electrical contact with the first impurity region.

In another embodiment consistent with the present invention, there is provided a method for fabricating a semiconductor device having a test pattern for measuring epitaxial pattern shift, the method comprising: forming a first pattern in a semiconductor substrate; forming a first impurity region in the semiconductor substrate; forming an epitaxial layer on the semiconductor substrate; forming a second pattern in the epitaxial layer, the second pattern corresponding to the first pattern; and forming a second impurity region in the epitaxial layer, the second impurity region in electrical contact with the first impurity region.

In still another embodiment consistent with the present invention, there is provided a method for measuring epitaxial pattern shift, the method comprising: fabricating a semiconductor device having a test pattern for measuring the epitaxial pattern shift, the test pattern including a semiconductor substrate having a first pattern formed therein, a first impurity region formed in the semiconductor substrate; an epitaxial layer formed on the semiconductor substrate, the epitaxial layer having a second pattern formed therein, wherein the second pattern corresponds to the first pattern, and a second impurity region formed in the epitaxial layer, the second impurity region in electrical contact with the first impurity region; and measuring resistance values by applying voltages to the test pattern.

### BRIEF DESCRIPTION OF THE DRAWINGS

FIGS. 1 to 3 are sectional views showing possible phenomena between a substrate and an epitaxial layer grown on the substrate;

FIGS. 4a to 4d are sectional views showing semiconductor device having a test pattern and a method for fabricating the same, according to an embodiment consistent with the present invention; and

FIGS. 5 to 7 are top views showing relative positions of a first impurity region and a second impurity region, according to the pattern shift.

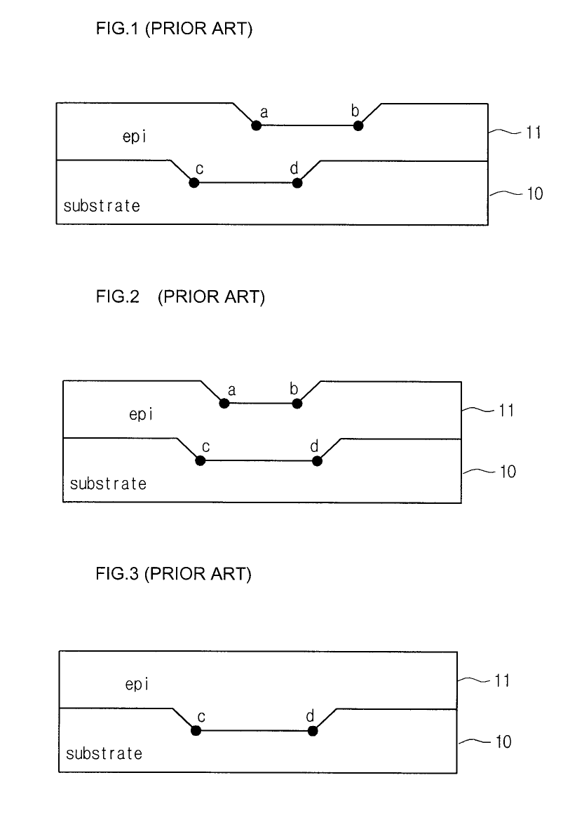

### DETAILED DESCRIPTION

Hereinafter, a semiconductor device having a test pattern for measuring epitaxial pattern shift, a method for fabricating the semiconductor device, and an epitaxial pattern shift measurement method, according to embodiments consistent with the present invention, will be described in detail with reference to the accompanying drawings.

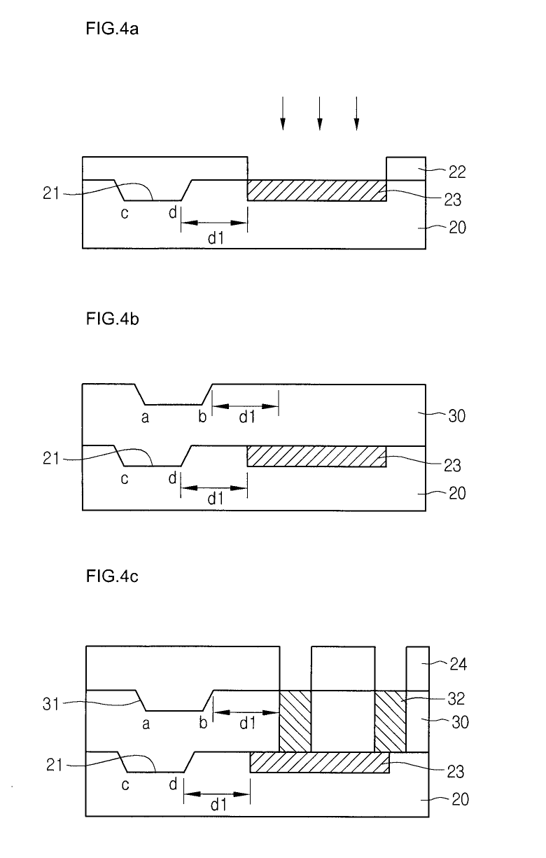

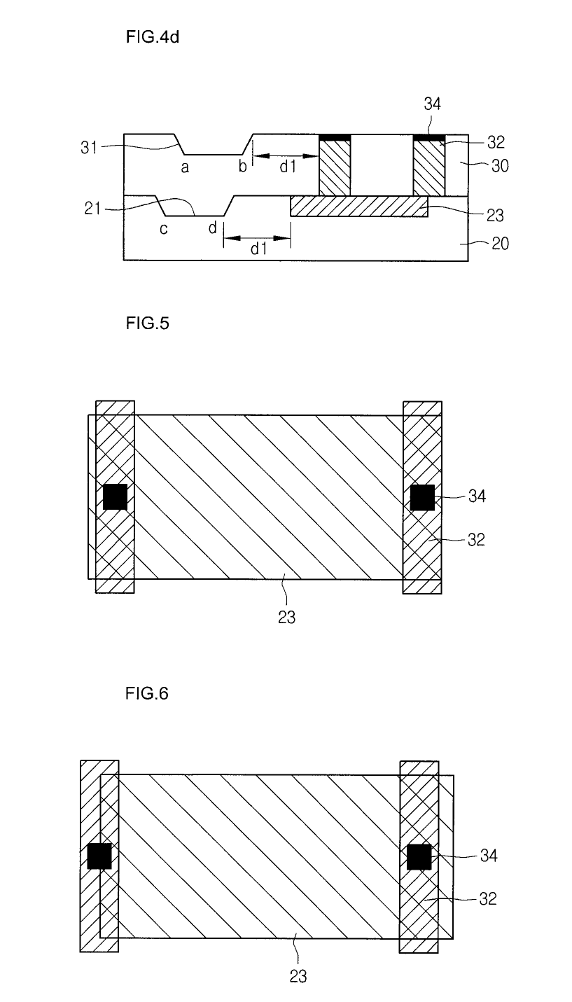

FIGS. 4a to 4d are sectional views showing a semiconductor device having a test pattern and a method for fabricating the same, according to an embodiment consistent with the present invention.

As shown in FIG. 4a, a first photoresist pattern 22 is formed on a semiconductor substrate 20 including a first pattern 21 formed therein. Impurity ions may be implanted into semiconductor substrate 20 using first photoresist pattern 22 as a mask to form a first impurity region 23. First impurity region 23 may be formed at a position spaced apart from first pattern 21 (reference point d) by a predetermined distance d1. Then, first photoresist pattern 22 is removed.

As shown in FIG. 4b, an epitaxial layer 30 is deposited on semiconductor substrate 20. During the deposition process, a second pattern 31 corresponding to first pattern 21 is formed on epitaxial layer 30. Second pattern 31 may be horizontally shifted on the upper portion of first pattern 21.

As shown in FIG. 4c, a second photoresist pattern 24 is formed on epitaxial layer Impurity ions may be selectively implanted into epitaxial layer 30 using second photoresist pattern 24 as a mask to form a second impurity region 32. Second impurity region 32 electrically contacts first impurity region 23, and may be formed at a position spaced apart from second pattern 31 (reference point b) by a predetermined distance d1.

As shown in FIG. 4d, second photoresist pattern 24 is removed, and the semiconductor device having the test pattern for measuring epitaxial pattern shift is completed. Contacts 34 may then be formed on second impurity region 32 to measure the resistance values of the test pattern.

By applying different voltages to contacts 34, resistance values of the test pattern may be measured. A final resistance value is obtained by taking an average of the measured resistance values. The final resistance value corresponds to the resistance between first impurity region 23 and second impurity region 32.

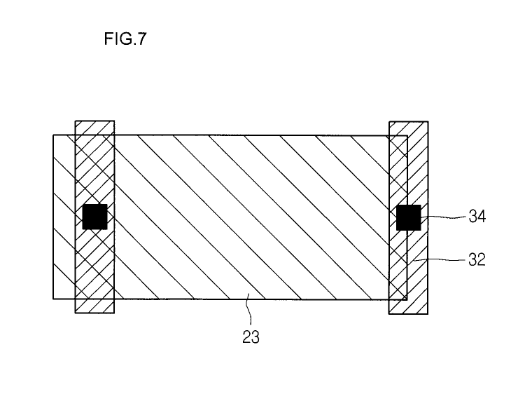

FIGS. 5 to 7 are top views illustrating relative positions of first impurity region 23 and the second impurity region 32. FIG. 5 shows a case in which no pattern shift exists, FIG. 6 shows a case in which the pattern shift occurs toward a left direction, and FIG. 7 shows a case in which the pattern shift occurs toward a right direction.

The different resistance values of first impurity region 23 and second impurity region 32 may be measured through contacts 34 indicating a pattern shift and the directions or the degree of the pattern shift. Accordingly, the resistance values are measured through test patterns, so that the pattern shift of the epitaxial layer can be precisely measured.

According to one embodiment consistent with the present invention, the pattern shift of a silicon epitaxial layer, which is not easily measured using a method in the related art, can be measured by simply measuring the resistance of a measurement pattern that serves as a test pattern used for electrically measuring the pattern shift.

Although embodiments consistent with the present invention have been described in detail, it should be understood that numerous other embodiments can be devised by those skilled in the art without departing from the spirit and scope of the appended claims. More particularly, various variations and modifications are possible in the component parts and/or arrangements of the subject combination arrangement within the scope of the appended claims. In addition to variations and modifications in the component parts and/or arrangements, alternative uses will also be apparent to those skilled in the art.

What is claimed is:

1. A semiconductor device having a test pattern formed therein for measuring epitaxial pattern shift, the test pattern comprising:
a semiconductor substrate having a first pattern formed therein;
a first impurity region formed in the semiconductor substrate;
an epitaxial layer formed on the semiconductor substrate, the epitaxial layer having a second pattern formed therein, wherein the second pattern corresponds to the first pattern; and
a second impurity region formed in the epitaxial layer, the second impurity region in electrical contact with the first impurity region.

2. The test pattern as claimed in claim 1, wherein the first impurity region is spaced apart from the first pattern by a predetermined distance, and the second impurity region is spaced apart from the second pattern by the predetermined distance.

3. The test pattern as claimed in claim 1, wherein the test pattern further comprises contacts formed on the second impurity region.

4. A method for fabricating a semiconductor device having a test pattern for measuring epitaxial pattern shift, the method comprising:
forming a first pattern in a semiconductor substrate;
forming a first impurity region in the semiconductor substrate;
forming an epitaxial layer on the semiconductor substrate;
forming a second pattern in the epitaxial layer, the second pattern corresponding to the first pattern; and
forming a second impurity region in the epitaxial layer, the second impurity region in electrical contact with the first impurity region.

5. The method as claimed in claim 4, wherein forming the first impurity region comprises forming the first impurity region spaced apart from the first pattern by a predetermined distance, and forming the second impurity region comprises forming the second impurity region spaced apart from the second pattern by the predetermined distance.

6. The method as claimed in claim 4, further comprising forming contacts on the second impurity region.

7. A method for measuring epitaxial pattern shift, the method comprising:
fabricating a semiconductor device having a test pattern for measuring the epitaxial pattern shift, the test pattern including a semiconductor substrate having a first pattern formed therein, a first impurity region formed in the semiconductor substrate; an epitaxial layer formed on the semiconductor substrate, the epitaxial layer having a second pattern formed therein, wherein the second pattern corresponds to the first pattern, and a second impurity region formed in the epitaxial layer, the second impurity region in electrical contact with the first impurity region; and
measuring resistance values by applying voltages to the test pattern.

8. The method as claimed in claim 7, wherein, measuring the resistance values further comprises applying different voltages in various directions, and calculating an average of the measured resistance values, thereby obtaining a final resistance value.
